(19) United States
(12) Patent Application Publication
(10) Pub. No.: US 2018/0174873 A1
(43) Pub. Date: Jun. 21, 2018

(54) Apparatus And Method For Processing Thin Substrates

(71) Applicant: Applied Materials, Inc., Santa Clara, CA (US)

(72) Inventor: Keith A. Miller, Mountain View, CA (US)

(21) Appl. No.: 15/840,219

(22) Filed: Dec. 13, 2017

Related U.S. Application Data
(60) Provisional application No. 62/434,498, filed on Dec. 15, 2016.

(51) Int. Cl. H01L 21/67; C23C 14/04; G03F 1/24; H05K 3/12; C23C 14/54; C23C 14/56

(52) U.S. Cl. CPC H01L 21/67167; C23C 14/042; C23C 14/568; H05K 3/1283; C23C 14/542; G03F 1/24

(57) ABSTRACT

Processing methods and apparatus for thin substrates are disclosed. The methods and apparatus rotate a thin substrate without exposing the thin substrate to pressure gradients. The apparatus and method can be part of an integrated system for depositing films on both sides of the thin substrate.

### CROSS-REFERENCE TO RELATED APPLICATIONS

This application claims priority to U.S. Provisional Application No. 62/434,498, filed Dec. 15, 2016, the entire disclosure of which is hereby incorporated by reference herein.

### TECHNICAL FIELD

The present disclosure relates generally to processing of thin substrates, and more particularly to processing thin substrates used in semiconductor processing such as those used to manufacture extreme ultraviolet mask blanks.

### BACKGROUND

The manufacture of integrated circuits includes handling of thin substrates, and may include substrates having a thickness in a range of 20-1000 nm. For example, in extreme ultraviolet (EUV) lithography (EUVL), also known as soft x-ray projection lithography, which can be used for the manufacture of 0.0135 micron and smaller minimum feature size semiconductor devices, a thin pellicle is used during manufacture of integrated circuits. More specifically, in EUVL a photomask, e.g., a reticle, may be repeatedly used to reproducibly print thousands of substrates to form integrated circuits. Typically, a reticle is a glass or a quartz substrate including a film stack having multiple layers, including a light-absorbing layer and an opaque layer disposed thereon. While performing the photolithography process, a pellicle is used to protect the reticle from particle contamination. A pellicle is a thin transparent membrane which allows lights and radiation to pass therethrough to the reticle. The pellicle is a relatively inexpensive, thin, transparent, flexible sheet, which is stretched above and not touching the surface of the mask. Pellicles provide a functional and economic solution to particulate contamination by mechanically separating particles from the mask surface.

Pellicles comprising silicon used in EUVL have a thickness in a range of about 20 and about 1000 nm, for example, in a range of about 20 and about 200 nm, more particularly in a range of about 20 and about 100 nm, for example in a range of about 30 and about 80 nm (e.g. about 50 nm). Silicon-based EUVL pellicles absorb EUV radiation, which can cause a sharp temperature rise in use, and for this reason coatings are sometimes applied to pellicles in a deposition chamber such as a physical vapor deposition (PVD) chamber. The pellicles are typically coated on both sides, and therefore, the pellicle must be placed into a deposition chamber and rotated 180 degrees or flipped over to provide a coating on both sides of the pellicle.

There is a need to provide apparatus and methods that can rotate thin substrates during process without damaging or breaking the thin substrates.

### SUMMARY

One or more embodiments of the disclosure are directed to a substrate processing apparatus comprising a substrate loading port configured to hold a thin substrate susceptible to damage upon exposure a gas pressure gradient exceeding about 5 Pascals and having a first side and a second side opposite the first side and a thickness between the first side and the second side in a range a range of about 20 nm and about 1000 nm, a rotatable chamber configured to rotate the thin substrate when placed in the rotatable chamber such that thin substrate can be oriented with the first side of the thin substrate or the second side of the thin substrate facing up without damaging the thin substrate, and a thin substrate holder in the rotatable chamber configured to hold the thin substrate during rotation of the thin substrate.

Another aspect pertains to thin substrate processing apparatus comprising a substrate loading port configured to hold a thin substrate susceptible to damage upon exposure a gas pressure gradient exceeding about 5 Pascals and having a first side and a second side opposite the first side and a thickness between the first and second side in a range a range of about 20 nm and about 1000 nm; a rotatable chamber configured to rotate the thin substrate when placed in the rotatable chamber such that thin substrate can be oriented with the first side of the thin substrate or the second side of the thin substrate facing up without damaging the thin substrate; a thin substrate holder in the rotatable chamber configured to hold the thin substrate during rotation of the thin substrate; a film deposition chamber configured to deposit films on the thin substrate; and a first loading arm configured to remove the thin substrate from the substrate loading port with the first side facing up, place the thin substrate in the rotatable chamber, remove the thin substrate from the rotatable chamber and move the thin substrate to be loaded in the film deposition chamber to deposit a thin film on the first side and second side of the thin substrate.

Another aspect of the disclosure pertains to a method of manufacturing an thin substrate comprising loading into a rotatable chamber a thin substrate susceptible to damage upon exposure a gas pressure gradient exceeding about 5 Pascals and having a first side and a second side opposite the first side and a thickness between the first side and the second side in a range a range of about 20 nm and about 1000 nm; rotating the rotatable chamber containing the thin substrate; removing the thin substrate from the rotatable chamber so that the first side is facing up; placing the thin substrate in a film deposition chamber; and depositing a film on the first side of the thin substrate, wherein the thin substrate is not damaged during rotating the rotatable chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates an embodiment of a semiconductor device production system including a substrate handling apparatus according to an embodiment;

FIG. 2A illustrates a perspective view of substrate handling apparatus according to an embodiment with a thin substrate being inserted into the apparatus;

FIG. 2B illustrates a perspective view of substrate handling apparatus according to an embodiment after the thin substrate has been inserted into the substrate handling apparatus;

FIG. 3 is a simplified side view of a substrate handling apparatus according to an embodiment;

FIG. 4A is a cross-sectional view of substrate handling apparatus according to an embodiment;

FIG. 4B is a cross-sectional view of substrate handling apparatus according to another embodiment;

FIG. 5 schematically illustrates an embodiment of an extreme ultraviolet lithography system; and

FIG. 6 illustrates a process flow diagram according to an embodiment.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “horizontal” as used herein is defined as a plane parallel to the plane or surface of a mask blank, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

Those skilled in the art will understand that the use of ordinals such as “first” and “second” to describe process regions do not imply a specific location within the processing chamber, or order of exposure within the processing chamber.

Processing methods and apparatus for thin substrates are disclosed. The methods and apparatus in one or more embodiments rotate a thin substrate without exposing the thin substrate to pressure gradients that damage or break the thin substrate. The apparatus and method can be part of an integrated system such as a vacuum cluster tool (e.g., ENDURA® processing platforms or CENTURA® processing platforms available from Applied Materials, Inc. located in Santa Clara, Calif.) for depositing films on both sides of the thin substrate. While the present disclosure provides exemplary embodiments of apparatus and methods for processing a pellicle which can be used in an EUV lithography system, it will be understood that the processes and apparatus described herein can be used for any thin substrate. Thus the present disclosure is not limited to a particular type of thin substrate.

It was discovered that in the processing of thin substrates to provide a coating on both sides of the substrate, rotation of the substrate could have a tendency to cause damage to the thin substrate. In particular, as noted above, pellicles used in EUVL (for example, silicon pellicles) have a thickness in a range of about 20 and about 1000 nm, for example, in a range of about 20 and about 200 nm, more particularly in a range of about 20 and about 100 nm, for example in a range of about 30 and about 80 nm (e.g. about 50 nm). Exposing a thin substrate within these thickness ranges to a pressure gradient exceeding about 10 Pascals, or about 5 Pascals, or about 4 Pascals, or about 3 Pascals or about 2 Pascals was sufficient to damage or break the thin substrate. In particular, exposure of an EUV pellicle having a thickness in a range of 30 nm and 80 nm to these pressure gradients could cause the EUV pellicle to be damaged or break the EUV pellicle such that pellicle could not be used in an EUV lithography system.

As mentioned above, there are thin substrates that require films to be deposited on both sides of the thin substrate. The films can be deposited by cyclical layer deposition (CLD), atomic layer deposition (ALD), chemical vapor deposition (CVD), or physical vapor deposition (PVD), which is typically accomplished in a chamber configured to achieve the particular type of deposition process. The deposition processes are typically configured to deposit a film on only one side of a substrate when placed in the film deposition chamber. Therefore, there is a need to rotate a thin substrate if a film needs to be deposited on both sides of thin substrate. For example, silicon-based EUVL pellicles absorb EUV radiation, which can cause a sharp temperature rise in use. Therefore, coatings or films are sometimes applied to pellicles in a deposition chamber such as a PVD, CLD, ALD or CVD chamber. Pellicles to be coated on both sides must be placed into a deposition chamber and rotated 180 degrees or flipped over to provide a coating on both sides of the pellicle.

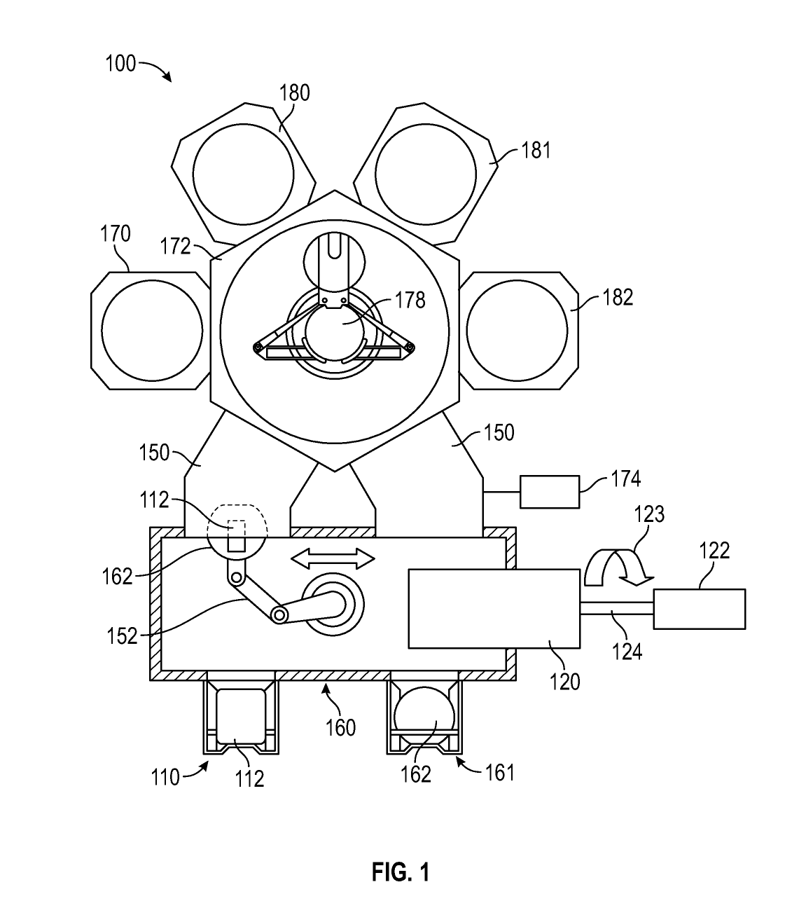

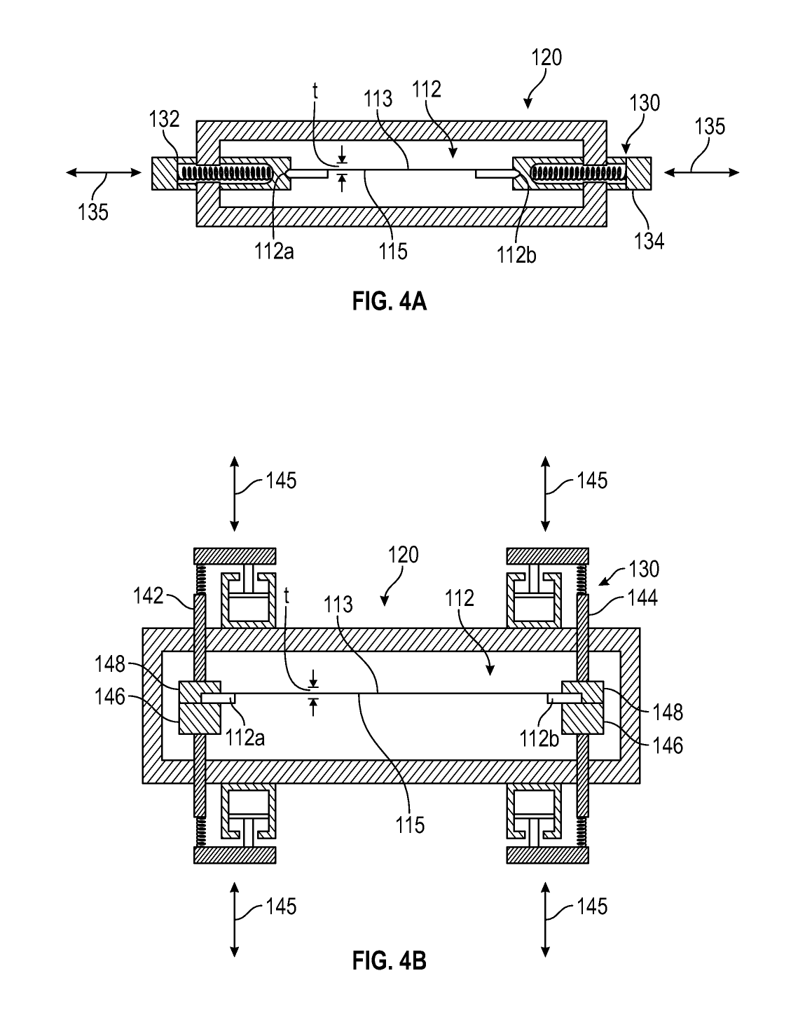

Rotating a thin substrate such as a EUV pellicle having a thickness in a range of about 20 and about 1000 nm, for example, in a range of about 20 and about 200 nm, more particularly in a range of about 20 and about 100 nm, for example in a range of about 30 and about 80 nm could cause the EUV pellicle to be damaged, broken or unusable. The rotation of the pellicle in the open atmosphere exposed the EUV pellicle to a pressure gradient greater than the thin substrate could withstand, damaging or breaking the thin pellicle. Rotation of the thin substrate in open atmosphere could expose the thin substrate to a pressure gradient exceeding about 10 Pascals, or about 5 Pascals, or about 4 Pascals, or about 3 Pascals or about 2 Pascals. In the case of an EUV pellicle having a thickness in a range of about 30 nm and 80 nm, exposure of the pellicle to a pressure gradient exceeding about 2 Pascals could damage or break the pellicle. Referring now to FIGS. 1 through 4A-B, embodiments of the disclosure provide a substrate processing apparatus 100 which includes a substrate loading port 110 adapted to or configured to hold a thin substrate 112. In an embodiment, the thin substrate 112 is susceptible to damage upon exposure a gas pressure gradient exceeding about 5 Pascals or exceeding 2 Pascals. In one embodiment, the substrate 112 has a first side 113 and a second side 115 opposite the first side 113 and a thickness “t” between the first side 113 and second side 115 (See FIG. 4A) in a range a range of about 20 nm and about 1000 nm. In specific embodiments, the thickness is in a range of about 20 and about 200 nm, more particularly in a range of about 20 and about 100 nm, for example in a range of about 30 and about 80 nm. In specific embodiments, the thin substrate 112 is an EUV pellice, more specifically, a silicon-based EUV pellicle.

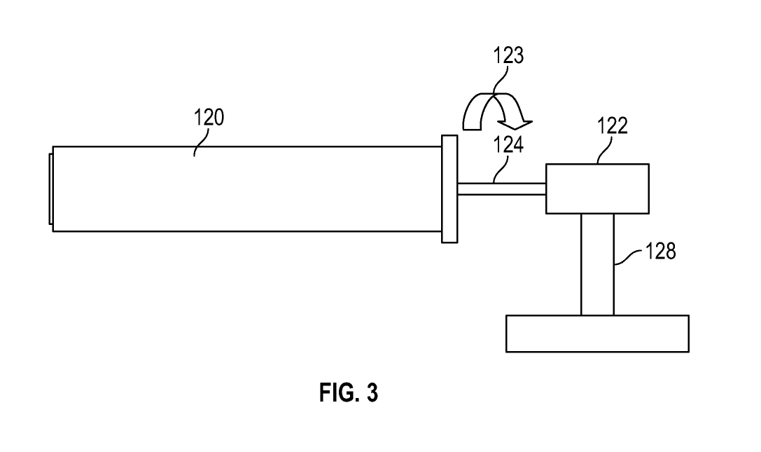

The apparatus 100 further comprises a rotatable chamber 120 adapted to or configured to rotate the thin substrate 112 when placed in the rotatable chamber 120 such that thin substrate 112 can be oriented with the first side 113 of the thin substrate 112 or the second side 115 of the thin substrate 112 facing up without damaging the thin substrate 112. An example of rotatable chamber that is adapted to or configured to rotate a thin substrate 112 when placed in the rotatable chamber is shown in FIGS. 1 through 4A-4B, and includes a motor 122 and a shaft 124 directly coupled to the rotatable chamber 120 such that the rotatable chamber 120 can be rotated about the axis of the shaft 124 as shown by arrow 123. The rotatable chamber 120 can be rotated about an axis in one direction as shown in FIGS. 1 and 3, or alternatively or in two directions as indicated by arrow 125 in FIGS. 4A and 4B. The rotatable chamber 120 can be configured to or adapted to rotate the thin substrate 112 when placed in the chamber in other ways, for example, by a motor having a gear that directly drives a complementary gear on the rotatable chamber 120. The motor 122 can be any suitable motor such as an alternating current motor or direct current motor. The rotatable chamber could also be adapted to or configured to rotate by a pneumatically or hydraulically rotatable shaft coupled to the rotatable chamber 120.

Referring to FIG. 3, the rotatable chamber 120, the shaft 124 and the motor 122 (or other suitable drive mechanism to rotate the rotatable chamber 120) can be mounted to a suitable stand 128. Referring to FIGS. 4A and 4B, the apparatus 100 further includes a thin substrate holder 130 in the rotatable chamber 120 configured to or adapted to hold the thin substrate 112 during rotation of the thin substrate 112.

Non-limiting examples of a substrate holder 130 that is configured to or adapted to hold a thin substrate 112 is shown in more detail in FIG. 4A and 4B. As shown in FIG. 4A a thin substrate holder 130 includes a pair of clamping members 132, 134 which can include springs 136, 136, the pair of clamping members 132, 134 configured to hold the thin substrate 112 at opposite edges 112a, 112b of the thin substrate 112. The clamping members 132, 134 can move in the direction indicated by arrows 135. The clamping members 132, 134 can be automatically controlled by a motor, pneumatic controls, hydraulic controls or manually actuated to move the clamping members 132, 134 in the directions of arrows 135 to effect clamping and securing the thin substrate 112 in the rotatable chamber 120 and to release the thin substrate 112 when the thin substrate 112 is to be removed from the rotatable chamber 120. Thus, FIG. 4A provides a pair of clamp members 132, 134 configured to or adapted to engage the thin substrate 112 from opposite edges 112a, 112b of the thin substrate 112. FIG. 4B shows an embodiment of a pair of clamping members 142, 144 adapted to or configured to engage the thin substrate 112 from the first side 113 and the second side 115. In particular, the clamping members 142, 144 include a lower shelf 146 and upper grip 148, both of which can be moved in the direction indicated by arrows 145. Thus, upon loading of the thin substrate 112 upon shelf 146, the upper grip 148 can be actuated to move down to engage the edges 112a, 112b of the thin substrate. The upper grip 148 and lower shelf 146 can be independently actuated. The upper grip 148 and lower shelf 146 can be automatically controlled by a motor, pneumatic controls, hydraulic controls or manually actuated to move the upper grip 148 and lower shelf 146 in the directions of arrows 145 to effect clamping and securing the thin substrate 112 in the rotatable chamber 120 and to release the thin substrate 112 when the thin substrate 112 is to be removed from the rotatable chamber 120.

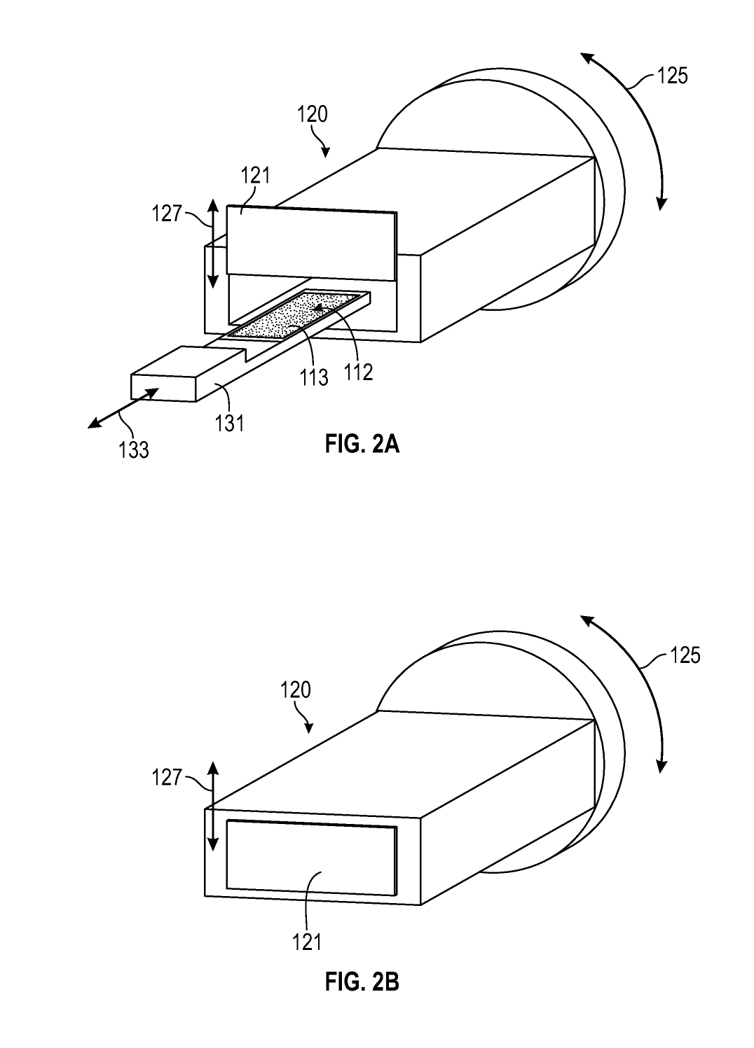

Referring to FIGS. 2A and 2B, the rotatable chamber 120 may further include a door 121 that can be moved in the direction of arrow 127 to open and close the chamber. FIG. 2A show the rotatable chamber 120 door 121 in an open position with a thin substrate 112 with a first side 113 facing up while being loaded in the rotatable chamber 120. The loading can be achieved by manually loading the thin substrate 112 using a blade, spatula or other suitable device such as a blade 131 of a robot arm or end effector, which can move in the direction of arrow 133 to load and unload thin substrates 112 from the rotatable chamber 120.

Referring back to FIG. 1, the substrate processing apparatus 100 can further include the substrate loading port 110 adapted to or configured to hold a thin substrate 112. A loading port adapted to or configured to hold a thin substrate has a size and shape to hold a thin substrate 112 in place for loading and unloading into the rotatable chamber 120. The apparatus 100 further includes a load lock chamber 150 and a first loading arm 152 adapted to or configured to remove the thin substrate 112 from the loading port 110 with the first side 113 facing up, place the thin substrate 112 in the rotatable chamber 120, remove the thin substrate 112 from the rotatable chamber 120 and move the thin substrate 112 to the load lock chamber 150. A first loading arm 152 that is adapted to or configured to move the substrate as described immediately above can include in the form of a robot within a factory interface 160 with an end effector or blade 131 that can move the thin substrate 112 between the loading port 110, the rotatable chamber 120, and the load lock chamber 150. The first loading arm 152 is capable of transferring a thin substrate 112 from the loading port 110 through the factory interface 160 to the rotatable chamber 120 and to the load lock chamber 150. The first loading arm 152 is also capable of transferring a wafer from the load lock chamber 150 through the factory interface 160 to a carrier load port 161 having a carrier which can be used to transport thin substrates 112 into the load lock chamber. As will be understood by those skilled in the art, the factory interface 160 can have more than loading arm in the form of a robot arm. For example, the factory interface 160 may have a first loading arm 152 in the form of a robot arm that transfers wafers between the loading port 110 and rotatable chamber, and a second loading arm in the form of a robot arm that transfers wafers between the rotatable chamber 120 and the carrier load port 161. An example of a suitable loading arm in the form of a robot arm is a VHP® substrate transfer robot, available from Applied Materials, Inc.

Still referring to FIG. 1, the rotatable chamber 120 can be integrated into a system including at least one film deposition chamber 170 in communication with the load lock chamber 150, the film deposition chamber 170 adapted to or configured to deposit a film on the thin substrate 112. The film deposition chamber 170 adapted to or configured to deposit a thin film on the thin substrate 112 can be a PVD, CLD, ALD or CVD chamber. In an embodiment, the load lock chamber 150 is coupled to a transfer chamber 172 and facilitates passage of thin substrates 112 between the substantially ambient atmosphere of the factory interface 160 and a vacuum environment of the transfer chamber 172. In an embodiment, the load lock chamber 150 is selectively isolated from the factory interface 160 and the transfer chamber 172 by slit valves (not shown). In an embodiment, an atmosphere control system 174 is coupled to the load lock chamber 150 to pump down and vent the interior volume of the load lock chamber 150 as the thin substrate 112 is transferred through the load lock chamber 150 between the factory interface 160 and the transfer chamber 172. In an embodiment, the apparatus 100 further comprises a second loading arm 178 configured to move the thin substrate from the load lock chamber 150 to the transfer chamber 172 and the film deposition chamber 102 and from the film deposition chamber 170 to transfer chamber 172 and the load lock chamber 150. An example of a suitable loading arm is in the form of a robot arm is a VHP® substrate transfer robot, available from Applied Materials, Inc. Additional substrate processing chambers 180, 182, 184 which can perform a variety of deposition, etching and cleaning processes on substrates.

Thus, an embodiment of the disclosure pertains to a thin substrate processing apparatus 100 comprising a substrate loading port 110 configured to hold a thin substrate 112 susceptible to damage upon exposure a gas pressure gradient exceeding about 5 Pascals and having a first side 113 and a second side 115 opposite the first side 113 and a thickness between the first side and the second side in a range a range of about 20 nm and about 1000 nm, a rotatable chamber 120 configured to rotate the thin substrate when placed in the rotatable chamber 120 such that thin substrate 112 can be oriented with the first side 113 of the thin substrate or the second side 115 of the thin substrate facing up without damaging the thin substrate 112 and a thin substrate holder 130 in the rotatable chamber 120 configured to hold the thin substrate during rotation of the thin substrate. The apparatus in this embodiment includes a film deposition chamber 170 configured to deposit films on the thin substrate 112 and a first loading arm 152 configured to remove the thin substrate 112 from the loading port 110 with the first side 113 facing up, place the thin substrate 112 in the rotatable chamber 120, remove the thin substrate 112 from the rotatable chamber and move the thin substrate 112 to be loaded in the film deposition chamber 170 to deposit a thin film on the first side 113 and second side 115 of the thin substrate.

In an embodiment, the thin substrate processing apparatus can include a load lock chamber 150 positioned between the rotatable chamber 120 and the film deposition chamber 170 such that the first loading arm 152 is configured to move the thin substrate from the rotatable chamber 120 to the load lock chamber 150 prior to loading in the film deposition chamber 170. Thus, the thin substrate processing apparatus 100 can further comprise a second loading arm 168 configured to move the thin substrate 112 from the load lock chamber 150 to the film deposition chamber 170 and from the film deposition chamber to the load lock chamber 150. In this embodiment the thin substrate 112 is typically on a carrier 162 retrieved from carrier load port 161 by first loading arm 152. In an embodiment, the rotatable chamber 120 is configured to prevent the thin substrate 112 from being exposed to a pressure gradient less than about 2 Pascals during rotation.

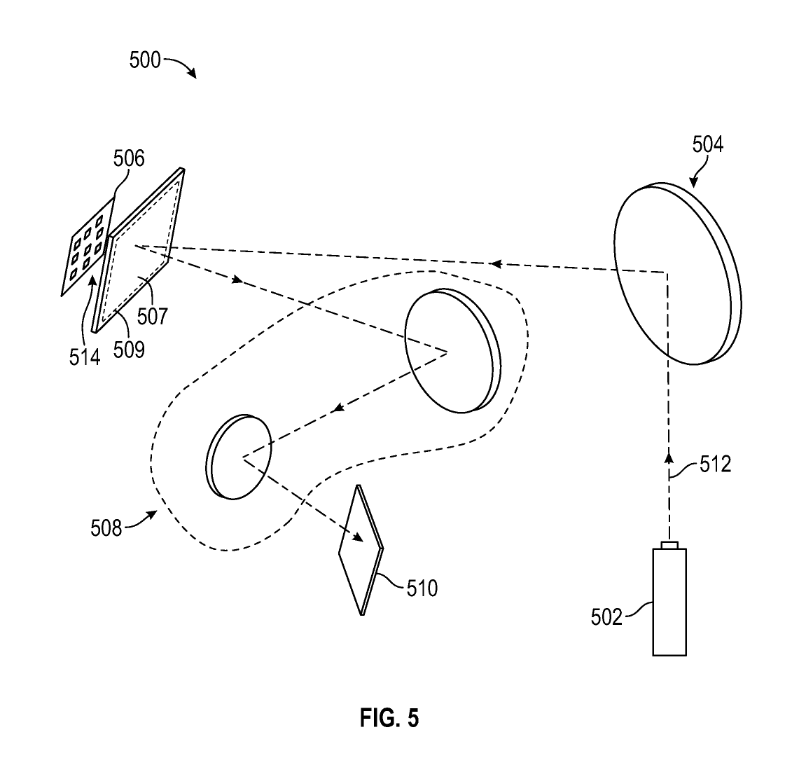

Referring now to FIG. 5, an exemplary embodiment of an extreme ultraviolet lithography system 500 is shown using a pellicle produced in the apparatus 100. The extreme ultraviolet lithography system 500 includes an extreme ultraviolet light source 502 for producing extreme ultraviolet light 512, a set of reflective elements, and a target wafer 510. The reflective elements include a condenser 504, an EUV reflective mask 506 having a pellicle 507 with a frame 509, an optical reduction assembly 108, a mask blank, a mirror, or a combination thereof. The pellicle 507 is shown as being separated from the EUV reflective mask 506 for clarity, but in use, the pellicle 507 is stretched above and is placed in close proximity to but not touching the EUV reflective mask 506. The pellicle 507 mechanically separates particles from the EUV reflective mask 506.

The extreme ultraviolet light source 502 generates the extreme ultraviolet light 512. The extreme ultraviolet light 512 is electromagnetic radiation having a wavelength in a range of 5 to 50 nanometers (nm). For example, the extreme ultraviolet light source 502 includes a laser, a laser produced plasma, a discharge produced plasma, a free-electron laser, synchrotron radiation, or a combination thereof.

In one embodiment, the extreme ultraviolet light source 502 generates the extreme ultraviolet light 512 having a variety of characteristics. The extreme ultraviolet light source 502 produces broadband extreme ultraviolet radiation over a range of wavelengths. For example, the extreme ultraviolet light source 502 generates the extreme ultraviolet light 512 having wavelengths ranging from 5 to 50 nm.

In one or more embodiments, the extreme ultraviolet light source 502 produces the extreme ultraviolet light 512 having a narrow bandwidth. For example, the extreme ultraviolet light source 502 generates the extreme ultraviolet light 512 at 13.5 nm. The center of the wavelength peak is 13.5 nm. The condenser 504 is an optical unit for reflecting and focusing the extreme ultraviolet light 512. The condenser 504 reflects and concentrates the extreme ultraviolet light 512 from the extreme ultraviolet light source 502 to illuminate the EUV reflective mask 506.

Although the condenser 504 is shown as a single element, it is understood that the condenser 504 can include one or more reflective elements such as concave mirrors, convex mirrors, flat mirrors, or a combination thereof, for reflecting and concentrating the extreme ultraviolet light 512. For example, the condenser 504 can be a single concave mirror or an optical assembly having convex, concave, and flat optical elements.

The EUV reflective mask 506 is an extreme ultraviolet reflective element having a mask pattern 514. The EUV reflective mask 506 creates or prints a lithographic pattern to form a circuitry layout to be formed on the target wafer 510. The EUV reflective mask 506 reflects the extreme ultraviolet light 512. The mask pattern 514 defines a portion of a circuitry layout.

The optical reduction assembly 508 is an optical unit for reducing the image of the mask pattern 514. The reflection of the extreme ultraviolet light 512 from the EUV reflective mask 506 is reduced by the optical reduction assembly 508 and reflected on to the target wafer 510. The optical reduction assembly 508 can include mirrors and other optical elements to reduce the size of the image of the mask pattern 514. For example, the optical reduction assembly 508 can include concave mirrors for reflecting and focusing the extreme ultraviolet light 512.

In operation, the optical reduction assembly 508 reduces the size of the image of the mask pattern 514 on the target wafer 510. For example, the mask pattern 514 can be imaged at a 4:1 ratio by the optical reduction assembly 508 on the target wafer 510 to form the circuitry represented by the mask pattern 514 on the target wafer 510. The extreme ultraviolet light 512 can scan the EUV reflective mask 506 synchronously with the target wafer 510 to form the mask pattern 514 on the target wafer 510.

Another aspect of the disclosure pertains to a method of manufacturing an thin substrate comprising loading into a rotatable chamber a thin substrate susceptible to damage upon exposure a gas pressure gradient exceeding about 5 Pascals and having a first side and a second side opposite the first side and a thickness between the first and second side in a range a range of about 20 nm and about 1000 nm, then rotating the rotatable chamber containing the thin substrate, removing the thin substrate from the rotatable chamber so that the first side is facing up, placing the thin substrate in a film deposition chamber, and depositing a film on the first side of the thin substrate, wherein the thin substrate is not damaged during rotating the rotatable chamber.

The method according to one or more embodiments can include removing the thin substrate having the film on the first side from the deposition chamber, loading the thin substrate into the rotatable chamber with the first side facing up, rotating the chamber so that the second side of the thin substrate is facing up, removing the thin substrate from the rotatable chamber so that the first side is facing up, placing the thin substrate in the film deposition chamber with the second side facing up, and depositing a film on the second side of the thin substrate, wherein the thin substrate is not damaged during rotating the rotatable chamber. In one or more embodiments, the thin substrate is not exposed to a pressure gradient exceeding about 5 Pascals during rotating. In one or more embodiments, the thin substrate is not exposed to a pressure gradient exceeding about 2 Pascals during rotating.

The method can further include securing the thin substrate in the rotatable chamber with a pair of clamps prior to rotating the rotatable chamber. In one or more embodiments, the thin substrate is an extreme ultraviolet pellicle having a thickness in a range of about 20 and 100 nm, for example, an extreme ultraviolet pellicle having a thickness in a range of 30 and 80 nm. In one embodiment of the method, the film deposition chamber is a physical vapor deposition chamber. In one embodiment, the film deposition chamber deposits a ruthenium or gold film on the pellicle.

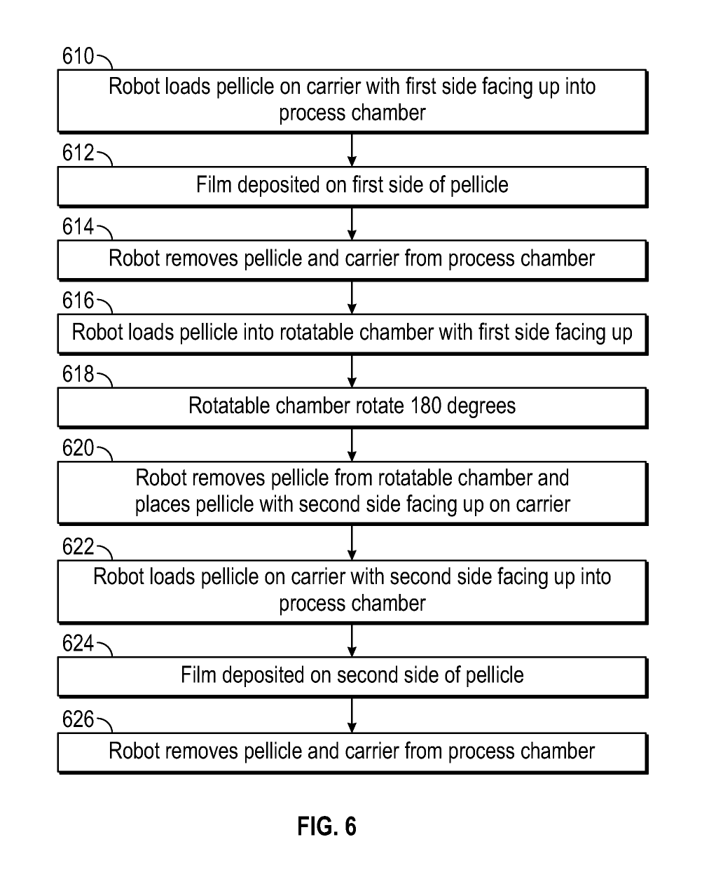

FIG. 6 provides a flow chart of an exemplary process according to one or more embodiments. In step 610 a loading arm such as a robot arm loads a pellicle on a carrier with a first side facing up into a process chamber such as a film deposition chamber, for example a PVD or CVD chamber that deposits films such as ruthenium or gold films. A film is deposited on the first side of the pellicle in step 612. A loading arm such as a robot arm removes the pellicle on the carrier from the process chamber in step 614, and in step 616, a loading arm in such as a robot arm loads the pellicle into a rotatable chamber with the first side facing up. In step 618, the rotatable chamber is rotated about 180 degrees, and in step 620, a loading arm such as a robot arm removes the pellicle from the rotatable chamber and places the pellicle with the second side facing up on a carrier. In step 622, a loading arm such as a robot arm loads the pellicle on a carrier with the second side facing up into a process chamber, and in step 624, a film is deposited on the second side of the pellicle. A loading arm such as a robot arm removes the pellicle and carrier from the process chamber in step 626, providing a pellicle having a film or coating on the first side and second side. The pellicle survives the processing because the pellicle has not been exposed to a pressure gradient greater than about 10 Pascals, greater than about 5 Pascals, greater than about 4 Pascals or greater than about 2 Pascals during rotation of the pellicle in the rotatable chamber.

Thus, one or more embodiments the present disclosure provides apparatus and methods which provide the advantageous effect of avoiding or preventing damage to thin substrates during handling. One or more embodiments the present disclosure provides apparatus and methods which provide the advantageous effect avoiding or preventing breakage to thin substrates during handling of thin substrates such as EUV pellicles. In particular, embodiments of the method and apparatus provide the advantageous effect that such thin substrates and pellicles can be processed in a film deposition apparatus so that both sides of the substrate can be coated with a film in a film deposition chamber as described herein. Another advantageous effect according to one or more embodiments of the methods and apparatus is improved productivity and reduced lost parts and production time in the manufacture of EUV reticles and EUV lithography systems.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A substrate processing apparatus comprising:
a substrate loading port configured to hold a thin substrate susceptible to damage upon exposure a gas pressure gradient exceeding about 5 Pascals and having a first side and a second side opposite the first side and a thickness between the first side and the second side in a range a range of about 20 nm and about 1000 nm;
a rotatable chamber configured to rotate the thin substrate when placed in the rotatable chamber such that thin substrate can be oriented with the first side of the thin substrate or the second side of the thin substrate facing up without damaging the thin substrate; and
a thin substrate holder in the rotatable chamber configured to hold the thin substrate during rotation of the thin substrate.

2. The substrate processing apparatus of claim 1, the thin substrate holder comprising a pair of clamping members configured to hold the thin substrate at opposite edges of the thin substrate.

3. The substrate processing apparatus of claim 2, wherein a pair of clamp members are configured to engage the thin substrate from the first side and the second side.

4. The substrate processing apparatus of claim 2, wherein the pair of clamping members are configured to engage the thin substrate from opposite edges of the thin substrate.

5. The substrate processing apparatus of claim 1, further comprising: a loading port;
a load lock chamber;
a first loading arm configured to remove the thin substrate from the loading port with the first side facing up, place the thin substrate in the rotatable chamber, remove the thin substrate from the rotatable chamber and move the thin substrate to the load lock chamber; and
a film deposition chamber in communication with the load lock chamber configured to deposit a film on the thin substrate.

6. The substrate processing apparatus of claim 5, wherein the film deposition chamber comprises a physical vapor deposition chamber.

7. The substrate processing apparatus of claim 5, further comprising a second loading arm configured to move the thin substrate from the load lock chamber to the film deposition chamber and from the film deposition chamber to the load lock chamber.

8. A thin substrate processing apparatus comprising:
a substrate loading port configured to hold a thin substrate susceptible to damage upon exposure a gas pressure gradient exceeding about 5 Pascals and having a first side and a second side opposite the first side and a thickness between the first and second side in a range a range of about 20 nm and about 1000 nm;
a rotatable chamber configured to rotate the thin substrate when placed in the rotatable chamber such that thin substrate can be oriented with the first side of the thin substrate or the second side of the thin substrate facing up without damaging the thin substrate;
a thin substrate holder in the rotatable chamber configured to hold the thin substrate during rotation of the thin substrate;
a film deposition chamber configured to deposit films on the thin substrate; and
a first loading arm configured to remove the thin substrate from the substrate loading port with the first side facing up, place the thin substrate in the rotatable chamber, remove the thin substrate from the rotatable chamber and move the thin substrate to be loaded in the film deposition chamber to deposit a thin film on the first side and second side of the thin substrate.

9. The thin substrate processing apparatus of claim 8, further comprising a load lock positioned between the rotatable chamber and the film deposition chamber such that the first loading arm is configured to move the thin substrate from the rotatable chamber to a load lock chamber prior to loading in the film deposition chamber.

10. The thin substrate processing apparatus of claim 9, further comprising a second loading arm configured to move the thin substrate from the load lock chamber to the film deposition chamber and from the film deposition chamber to the load lock chamber.

11. The thin substrate processing apparatus of claim 10, wherein the rotatable chamber is configured to prevent the thin substrate from being exposed to a pressure gradient less than about 2 Pascals.

12. A method of manufacturing an thin substrate comprising:
loading into a rotatable chamber a thin substrate susceptible to damage upon exposure a gas pressure gradient exceeding about 5 Pascals and having a first side and a second side opposite the first side and a thickness between the first side and the second side in a range a range of about 20 nm and about 1000 nm;
rotating the rotatable chamber containing the thin substrate;
removing the thin substrate from the rotatable chamber so that the first side is facing up;
placing the thin substrate in a film deposition chamber; and
depositing a film on the first side of the thin substrate, wherein the thin substrate is not damaged during rotating the rotatable chamber.

13. The method of claim 12, further comprising:
removing the thin substrate having the film on the first side from the film deposition chamber;
loading the thin substrate into the rotatable chamber with the first side facing up;
rotating the rotatable chamber so that the second side of the thin substrate is facing up;
removing the thin substrate from the rotatable chamber so that the first side is facing up;
placing the thin substrate in the film deposition chamber with the second side facing up; and
depositing a film on the second side of the thin substrate, wherein the thin substrate is not damaged during rotating the rotatable chamber.

14. The method of claim 13, wherein the thin substrate is not exposed to a pressure gradient exceeding about 5 Pascals during rotating.

15. The method of claim 13, wherein the thin substrate is not exposed to a pressure gradient exceeding about 2 Pascals during rotating.

16. The method of claim 13, further comprising securing the thin substrate in the rotatable chamber with a pair of clamps prior to rotating the rotatable chamber.

17. The method of claim 12, wherein the thin substrate is an extreme ultraviolet pellicle having a thickness in a range of about 20 and 100 nm.

18. The method of claim 17, wherein the extreme ultraviolet pellicle has a thickness in a range of 30 and 80 nm.

19. The method of claim 15, wherein the film deposition chamber is a physical vapor deposition chamber.

20. The method of claim 19, wherein the film deposition chamber deposits a ruthenium film on the pellicle.
